(19) United States
(12) Patent Application Publication
(10) Pub. No.: US 2010/0165772 A1
(43) Pub. Date: Jul. 1, 2010

(54) Self aligned back-gate for floating body cell memory erase

(76) Inventors: Uygar E. Avci, Beaverton, OR (US); Peter L. D. Chang, Portland, OR (US); David L. Kencke, Beaverton, OR (US)

Correspondence Address: INTEL CORPORATION;c/o CPA Global, P.O. BOX 52050, MINNEAPOLIS, MN, 55402, US

(21) Appl. No.: 12/319,103

(22) Filed: Dec. 30, 2008

(51) Int. Cl. G11C 7/00

(52) U.S. Cl. 365/218; 365/189.011

(57) ABSTRACT

In some embodiments all cells within a word-line of a floating body cell memory are erased. A back-gate of the floating body cell memory is self-aligned with the word line, and the erasing is performed using a back-gate bias. Other embodiments are described and claimed.

### TECHNICAL FIELD

The inventions generally relate to self aligned back-gate for floating body cell memory erase.

### BACKGROUND

In a conventional floating body cell (FBC) semiconductor architecture, an erase operation of a memory cell may be accomplished by combining a negative source-line (SL) or bit-line (BL) bias with a positive word-line (WL) bias. This technique requires very high current and power, and does not remove all holes from the body. Using this technique, full advantage of the signal capability of the cell is not available since the conventional erase operation is limited by not removing all holes. Therefore, the current state of the art has a limited signal and high current required during the erase operation.

FIG. 1 illustrates sample voltage biases during a conventional floating body cell (FBC) hold operation 102 and a conventional floating body cell (FBC) erase operation 104. In order to erase the cell, the gate is biased positively to increase the body potential and the source (which can be connected to either the source-line or the bit-line of the array) is biased with a high negative voltage. Thus, the body-to-source pn-junction is forward biased and holds are removed from the body. This conventional method uses high current (and power) due to the high source-drain bias and high gate voltage, and has reliability concerns due to high voltages. Additionally, this conventional erase operation become ineffective as the floating body cell (FBC) back-gate (BG) becomes more negative. Therefore, a need has arisen for a new improved FBC erase operation.

### BRIEF DESCRIPTION OF THE DRAWINGS

The inventions will be understood more fully from the detailed description given below and from the accompanying drawings of some embodiments of the inventions which, however, should not be taken to limit the inventions to the specific embodiments described, but are for explanation and understanding only.

FIG. 1 illustrates a conventional operation.

FIG. 2 illustrates an operation according to some embodiments of the inventions.

FIG. 3 illustrates a graph according to some embodiments of the inventions.

FIG. 4 illustrates a graph according to some embodiments of the inventions.

FIG. 5 illustrates a memory array according to some embodiments of the inventions.

FIG. 6 illustrates a memory array according to some embodiments of the inventions.

FIG. 7 illustrates a cross-section view of a memory array according to some embodiments of the inventions.

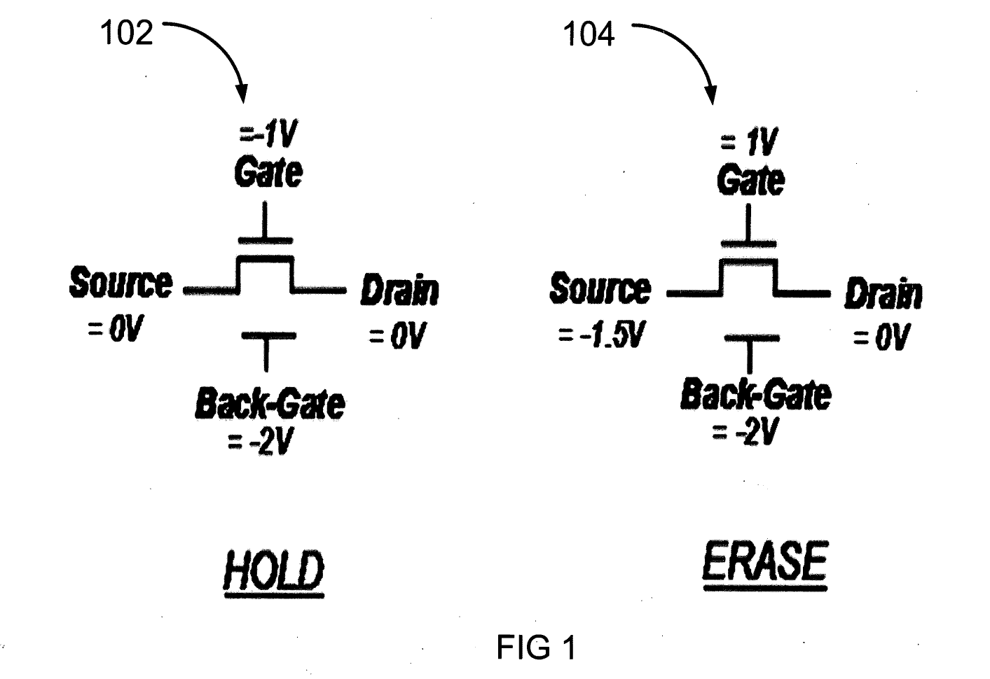

### DETAILED DESCRIPTION

Some embodiments of the inventions relate to self aligned back-gate for floating body cell memory erase.

In some embodiments all cells within a word-line of a floating body cell memory are erased. A back-gate of the floating body cell memory is self-aligned with the word line, and the erasing is performed using a back-gate bias.

In some embodiments, a floating body cell memory includes a word-line and a back-gate self-aligned to the word-line. The floating body cell memory is to use a back-gate bias to erase all cells within the word-line.

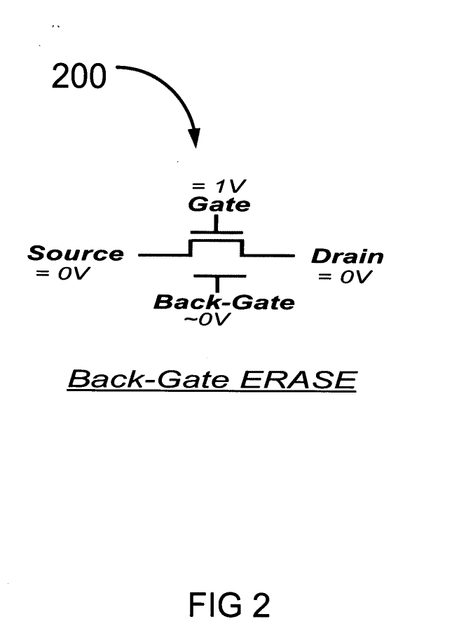

FIG. 2 illustrates an erase operation 200 according to some embodiments. In some embodiments, the erase operation 200 is referred to as a back-gate (BG) erase operation. FIG. 2 illustrates proposed voltages biases to erase a floating body cell (FBC) memory cell according to some embodiments. The back-gate (BG), whose negative bias is required to keep holes in the body, is biased up to zero or positive voltage. The potential well is lost in the back surface and holes are removed by combining with source and/or drain electrons.

As mentioned previously, conventional methods use high current (and power) due to a high source-drain bias and high gate-voltage. They also have reliability concerns due to high voltages. However, using a back-gate (BG) erase according to some embodiments (for example, as illustrated in FIG. 2), no transistor current occurs due to a zero source-drain bias. Leakage current between n-well and p-well regions occurs according to some embodiments due to a low reverse bias pn-junction current during a hold operation. According to some embodiments, dynamic power allows body-to-transistor capacitance charging that is significantly lower than conventional erase source-to-drain leakage. Further, conventional erase operations become ineffective as FBC BG voltage becomes more negative, which is not the case according to some embodiment of the present inventions.

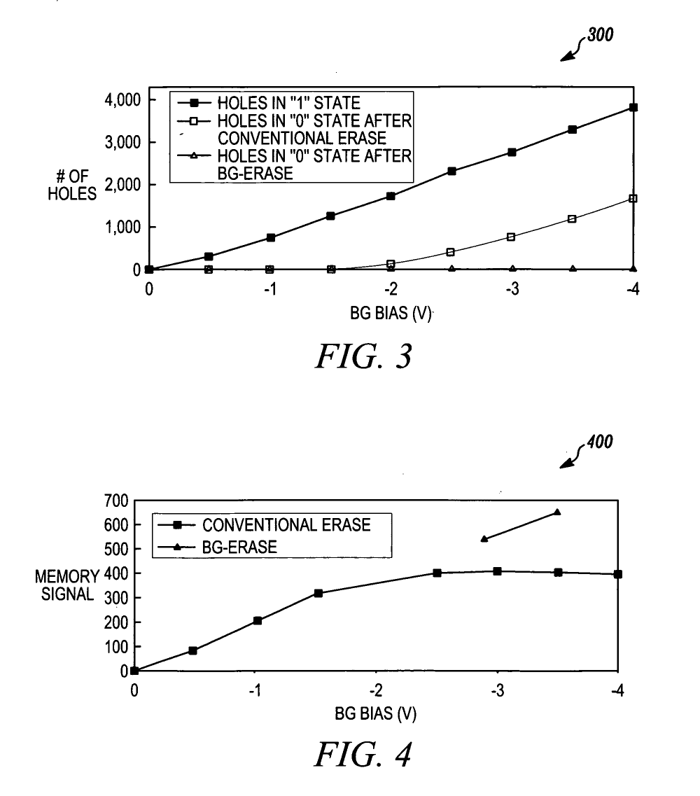

FIG. 3 illustrates a graph 300 according to some embodiments. Graph 300 shows the number of holes on the vertical axis and the BG voltage bias from zero to −4 on the horizontal axis. The top line in graph 300 shows the number of holes in the “1” state for various voltages, the middle line in graph 300 shows the number of holes in the “0” state after a conventional erase operation is performed, and the bottom line in graph 300 shows the number of holes in the “0” state after a BG-erase operation is performed according to some embodiments. As illustrated in graph 300, after the back-gate (BG) bias reaches a threshold value, a conventional erase operation does not remove all the holes from the body. However, when using BG erase according to some embodiments, all the holes are removed. This helps to achieve a larger signal difference between a “0” and “1” memory state value.

FIG. 4 illustrates a graph 400 according to some embodiments. Graph 400 shows a memory signal level on the vertical axis and the BG voltage bias on the horizontal axis. Graph 400 illustrates an increased memory signal level with BG erase according to some embodiments when compared with a conventional erase operation.

According to some embodiments, a back-gate (BG) erase operation can be performed in a simple manner. Although BG-erase has already been proposed for a single cell, without localized back-gate control, the back-gate is shared by the entire memory array. Thus, the entire array is erased when the back-gate is biased back-to-zero, setting the memory to the “0” state not only for the selected word-line (WL), but for all unselected word-lines (WLs) as well. Therefore, according to some embodiments, a BG-erase may be performed on a memory in an array without requiring all word-lines (selected and unselected) to be set back to “0”.

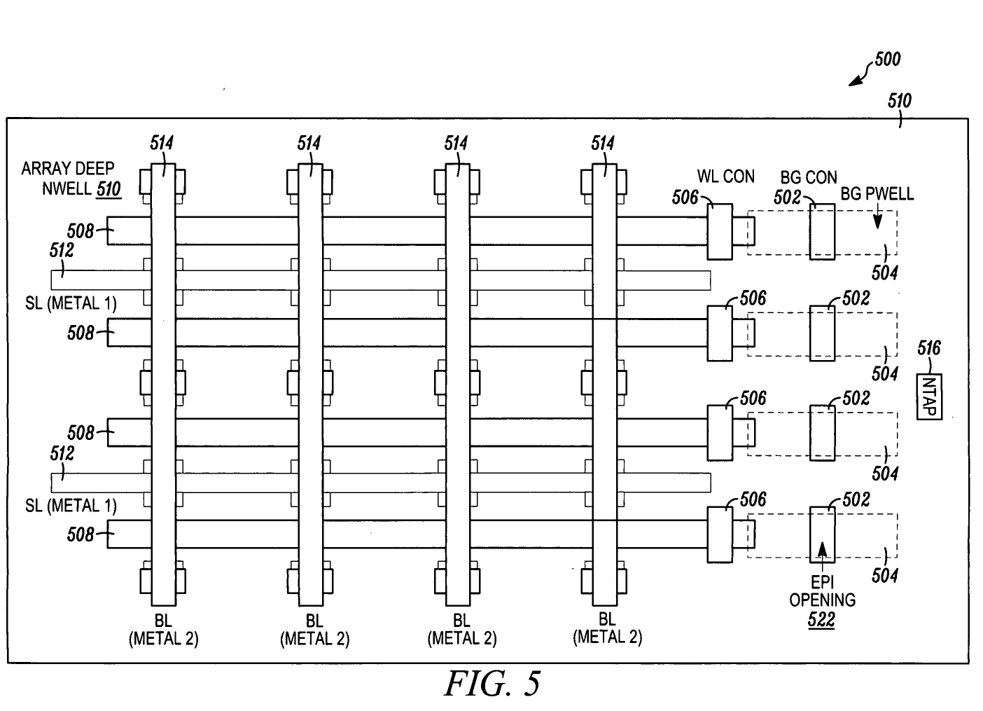

FIG. 5 illustrates a memory array 500 according to some embodiments. In some embodiments, memory array 500 includes back-gate (BG) conductors 502, back-gate (BG) Pwells 504, word-line (WL) conductors 506, word-lines (WL) 508, an array deep Nwell 510, source lines (SL) 512 (for example, metal 1), bit-lines (BL) 514 (for example, metal 2), a drain nWell NTap 516 (NTap is, for example, a conducting region that connects to the nWell layer), and an EPI opening 522 (the EPI opening is, for example, a selectively opened area to make an epitaxial silicon growth).

FIG. 5 illustrates local back-gate control according to some embodiments. As illustrated in FIG. 5, back-gate biases between neighboring back-gates are disconnected. In FIG. 5, the back-gate conductor 502 and the back-gate Pwell 504 are shared by a single word-line conductor 506 and word-line 508. This enables erasing of all cells across a single selected word-line by biasing its BG to zero. Then, a program “1” operation is performed by a high drain bias for all cells, which will change to the “1” state. A single pattern that covers the P-well extension from the WL 508 is enough to block this area, for example, during n-SD (n-type Source/Drain), n-TIP (n-type shallow doped region in the Source/Drain), and isolation N-well implants, for example.

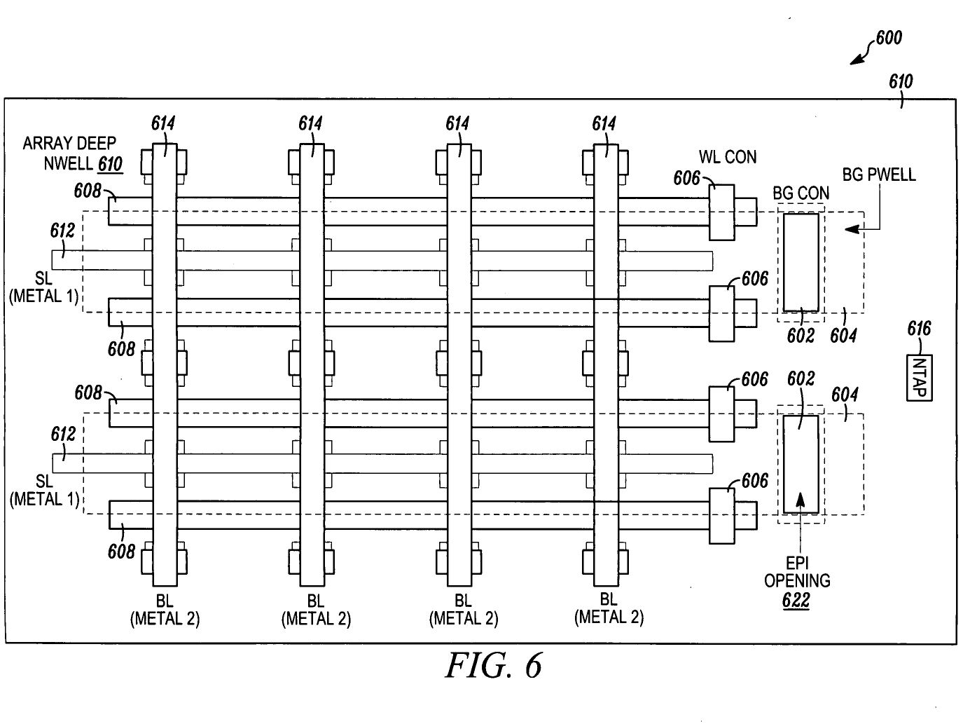

FIG. 6 illustrates a memory array 600 according to some embodiments. In some embodiments, memory array 600 includes back-gate (BG) conductors 602, back-gate (BG) Pwells 604, word-line (WL) conductors 606, word-lines (WL) 608, an array deep Nwell 610, source lines (SL) 612 (for example, metal 1), bit-lines (BL) 614 (for example, metal 2), a drain nWell NTap 616, and an EPI opening 622.

FIG. 6 illustrates local back-gate control according to some embodiments. As illustrated in FIG. 6, a single back-gate is shared by two neighboring WLs that share a common SL. During an erase operation, the BG is pulsed to a zero bias to remove the holes (“0” state) of all cells on both WLs. Then each neighboring WL is selected consecutively, and the states of the cells are determined by BL bias selection. In some embodiments, two different patternings are implemented. A pattern during n-SD and n-Tip implants is used that only blocks the P-well tap region. A pattern during the isolation N-well implant is used that blocks the entire P-well extensions, including the region neighboring WLs that share a SL.

In some embodiments as illustrated, for example, in FIG. 5 and FIG. 6, the P-well BG is self-aligned to the WL since the gate blocks the n-implant.

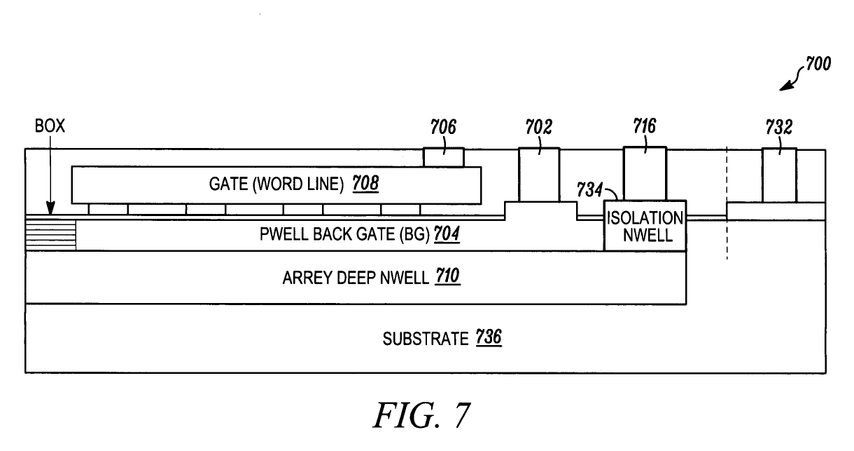

FIG. 7 illustrates a memory array 700 illustrated in a cross-section view according to some embodiments. In some embodiments, memory array 700 includes a back-gate (BG) conductor 702, a back-gate (BG) Pwell 704, a word-line (WL) conductor 706, a gate (word-line) (WL) 708, an array deep Nwell 710, a drain nWell NTap 716, a substrate PTap 732 (for example, a conducting region that connects to the substrate), an isolation NWell 734, and a substrate 736. Memory array 700 also includes a buried oxide (BOX) that is a thin oxide region located, for example, under the floating body cells.

FIG. 7 illustrates cross-sectional schematics cut through the word-line. The P-well BG 704 is shared by the word-line 708. The array deep Nwell 710 wraps under the P-well BG 704 and isolation N-well blocks 734 neighboring the BGs in a lateral direction.

In some embodiments, a self-aligned back-gate (BG) is provided for a floating body cell (FBC) memory erase. With a back-gate (BG) that is self aligned to the word-line (WL), all cells within a selected word-line can be erased with very low current, and all the holes in the body are removed by switching the back-gate from a negative bias to a zero bias, for example. In some embodiments, an erase using a back-gate bias is implemented on an FBC array in which the back-gate is self-aligned to the word-line. While a high current was required using conventional FBC erase operations, and removal of all body holes was ineffective, in some embodiments FBC signal levels are improved and the required erase current and power consumption is lowered.

Although some embodiments have been described herein as being implemented in a particular manner, according to some embodiments these particular implementations may not be required.

Although some embodiments have been described in reference to particular implementations, other implementations are possible according to some embodiments. Additionally, the arrangement and/or order of circuit elements or other features illustrated in the drawings and/or described herein need not be arranged in the particular way illustrated and described. Many other arrangements are possible according to some embodiments.

In each system shown in a figure, the elements in some cases may each have a same reference number or a different reference number to suggest that the elements represented could be different and/or similar. However, an element may be flexible enough to have different implementations and work with some or all of the systems shown or described herein. The various elements shown in the figures may be the same or different. Which one is referred to as a first element and which is called a second element is arbitrary.

In the description and claims, the terms “coupled” and “connected,” along with their derivatives, may be used. It should be understood that these terms are not intended as synonyms for each other. Rather, in particular embodiments, “connected” may be used to indicate that two or more elements are in direct physical or electrical contact with each other. “Coupled” may mean that two or more elements are in direct physical or electrical contact. However, “coupled” may also mean that two or more elements are not in direct contact with each other, but yet still co-operate or interact with each other.

An algorithm is here, and generally, considered to be a self-consistent sequence of acts or operations leading to a desired result. These include physical manipulations of physical quantities. Usually, though not necessarily, these quantities take the form of electrical or magnetic signals capable of being stored, transferred, combined, compared, and otherwise manipulated. It has proven convenient at times, principally for reasons of common usage, to refer to these signals as bits, values, elements, symbols, characters, terms, numbers or the like. It should be understood, however, that all of these and similar terms are to be associated with the appropriate physical quantities and are merely convenient labels applied to these quantities.

Some embodiments may be implemented in one or a combination of hardware, firmware, and software. Some embodiments may also be implemented as instructions stored on a machine-readable medium, which may be read and executed by a computing platform to perform the operations described herein. A machine-readable medium may include any mechanism for storing or transmitting information in a form readable by a machine (e.g., a computer). For example, a machine-readable medium may include read only memory (ROM); random access memory (RAM); magnetic disk storage media; optical storage media; flash memory devices; electrical, optical, acoustical or other form of propagated signals (e.g., carrier waves, infrared signals, digital signals, the interfaces that transmit and/or receive signals, etc.), and others.

An embodiment is an implementation or example of the inventions. Reference in the specification to “an embodiment,” “one embodiment,” “some embodiments,” or “other embodiments” means that a particular feature, structure, or characteristic described in connection with the embodiments is included in at least some embodiments, but not necessarily all embodiments, of the inventions. The various appearances “an embodiment,” “one embodiment,” or “some embodiments” are not necessarily all referring to the same embodiments.

Not all components, features, structures, characteristics, etc. described and illustrated herein need be included in a particular embodiment or embodiments. If the specification states a component, feature, structure, or characteristic “may”, “might”, “can” or “could” be included, for example, that particular component, feature, structure, or characteristic is not required to be included. If the specification or claim refers to “a” or “an” element, that does not mean there is only one of the element. If the specification or claims refer to “an additional” element, that does not preclude there being more than one of the additional element.

Although flow diagrams and/or state diagrams may have been used herein to describe embodiments, the inventions are not limited to those diagrams or to corresponding descriptions herein. For example, flow need not move through each illustrated box or state or in exactly the same order as illustrated and described herein.

The inventions are not restricted to the particular details listed herein. Indeed, those skilled in the art having the benefit of this disclosure will appreciate that many other variations from the foregoing description and drawings may be made within the scope of the present inventions. Accordingly, it is the following claims including any amendments thereto that define the scope of the inventions.

What is claimed is:

1. A method comprising:
erasing all cells within a word-line of a floating body cell memory in which a back-gate of the floating body cell memory is self-aligned with the word line, the erasing using a back-gate bias.

2. The method of claim 1, further comprising using a low current to perform the erasing.

3. The method of claim 1, further comprising removing all holes of all cells in the word-line of the floating body cell memory.

4. The method of claim 1, further comprising removing all holes of all cells in the word-line and a neighboring word-line of the floating body cell memory.

5. The method of claim 1, wherein the back-gate bias is zero or positive voltage.

6. A floating body cell memory comprising:
a word-line; and
a back-gate self-aligned to the word-line;
wherein the floating body cell memory is to use a back-gate bias to erase all cells within the word-line.

7. The floating body cell memory of claim 6, wherein the back-gate is aligned only with the single word-line.

8. The floating body cell memory of claim 6, wherein the back-gate is aligned only with the word-line and a neighboring word-line of the floating body cell.

9. The floating body cell memory of claim 8, further comprising a source-line, wherein the word-line and the neighboring word-line share the source-line.

10. The floating body cell memory of claim 6, wherein the floating body cell memory is to use a low current to perform the erasing.

11. The floating body cell memory of claim 6, wherein the floating body cell memory is to remove all holes of the cells in the word-line of the floating body cell memory to perform the erasing.

12. The floating body cell memory of claim 8, wherein the floating body cell memory is to remove all holes of the cells in the word-line and to remove all holes of the cells in the neighboring word-line to perform the erasing.

13. The floating body cell memory of claim 6, wherein the back-gate bias is zero or positive voltage.
